(19) United States
(12) Patent Application Publication
(10) Pub. No.: US 2018/0127878 A1
(43) Pub. Date: May 10, 2018

(54) COATING DEVICE OF COMPONENT FOR SEMICONDUCTOR MANUFACTURING APPARATUS AND COATING METHOD THEREOF

(71) Applicant: Do Hyeong LEE, Hwaseong-si (KR)

(72) Inventor: Do Hyeong LEE, Hwaseong-si (KR)

(21) Appl. No.: 15/346,738

(22) Filed: Nov. 9, 2016

(51) Int. Cl. C23C 16/50; C23C 16/34; H01J 37/32

(52) U.S. Cl. CPC C23C 16/50; H01J 2237/3321; H01J 37/32009; C23C 16/34

(57) ABSTRACT

A coating device of component for semiconductor manufacturing apparatus comprises a source among pulse type plasma source, ICP source, CCP source, CCP+ICP source and plasma source using a remote plasma to be carried out nitride treatment by a gas among N2, NH3, CH4 and N2O being supplied into a chamber; and a DC voltage for forming a plasma by said source and for supplying 50 KeV˜100 KeV of voltage toward a susceptor placed thereon with a basic material or a pulse voltage for injecting ion.

### BACKGROUND OF THE INVENTION

### 1. Field of the Invention

The present invention relates to a coating device of component for semiconductor manufacturing apparatus and coating method in that erosion resistance, decay resistance and plasma resistance of plasma can be improved by injecting ion into a shower head and an electrode made of aluminum, silicon and silicon carbide.

The present invention also relates to a coating device of component for semiconductor manufacturing apparatus and coating method thereof in that characteristic of a basic material can be improved by forming a coating layer made of ALN (aluminum nitride), SIN (silicon nitride), SICN (silicon carbide nitride), DLC (diamond like carbone), ALO (aluminum oxide), ALF (aluminum fluoride) and ALNO (aluminum nitride oxide) to the basic material facing to a heater or an electrostatic chuck or a face being supplied gas.

### 2. Description of the Related Art

A conventional semiconductor manufacturing apparatus as shown in FIG. 1 comprises a reaction chamber 10 including a heater 11 and a shower head 13. When a wafer 12 is placed on the heater 11, reaction gas which is flowed through a pipe 20 is supplied to the wafer 12 through the shower head 13 and simultaneously heating energy having a certain temperature is supplied by the heater 11 thereby be carried out semiconductor manufacturing process.

As described above, a vacuum chamber is mainly used for depositing a thin film for semiconductor. Furthermore, RF or corrosive gas is supplied into the chamber to improve characteristic and productivity of thin film process, component neighborhood of the chamber are generally made of an aluminum to be improved electric conductivity and erosion resistance.

However, the components made of aluminum have the problems that erosion resistance becomes weak by pin hole or bur which is produced during working or process characteristic is changed or foreign particle is produced by easily attaching by-products of reaction.

Accordingly, to solve the problems as above it is known as method that the component in the chamber is coated by anodizing technique. However, under a state of thin film deposition environment using a high temperature, the film formed by anodizing is detached to be occurred foreign particle and a process cannot be normally carried out as well after a certain period by a difference of thermal expansion coefficient between aluminum and anodizing film

Recently, the aluminum is being used as bare state even if the problems as above remain unchanged. A coefficient of thermal expansion is 23.03×10⁶/ [symbol] for aluminum and 6.87×10⁶ at 20 [symbol] ˜100 [symbol] , 8.33×10⁶ at 20 [symbol] ˜500 [symbol] for anodizing film. Accordingly, because there is heavy difference of the thermal expansion coefficient between the aluminum and the anodizing film it can not be solved the problem for example, detachment of the film, although a coefficient of the thermal expansion of the anodizing film is increased in proportion to temperature.

A conventional device for etching as shown in FIG. 2 comprises a reaction chamber 10 including an electrostatic chuck 15, a cathode 16 and an edge ring 17. Under this state, when a wafer 11 is disposed for etching, reaction gas which is flowed through a pipe 20 is supplied to the wafer 12 through the cathode 16 for the semiconductor manufacturing process after the electrostatic chuck 15 operates to fix the wafer

As the above description, a vacuum chamber is mainly used for the etching process of the semiconductor and plasma and erosion gas, for example SF6, CF4, Cl2, NF3, BCl3, O2 are supplied into the chamber and the cathode made of Si and the edge ring made of SiC or ceramic are used for improving process characteristic. However, Si and SiC are shorten their life because the reaction chamber is filled with plasma and erosion gas.

To solve the problems as above, there have been studied about erosion by reaction gas, foreign particles by accumulating by-products and shorten life as the use of method that Al, Ni and Hastelloy as a kind of Ni alloy and Inconel, Si and SiC are used to make a basic material.

However, a conventional method, for example anodizing coating and melting coating have the problem that there is occurred detachment of film by a difference of thermal expansion coefficient between a basic material and the coated film.

In particular, the shower head as the component in the vacuum chamber is placed on the upper face of the wafer for depositing. Accordingly, the state of surface can be changed by erosion or the foreign particles can be easily produced by depositing the by-products of reaction. Furthermore, the process has not reproducibility. Further, the life of Si electrode and SiC edge ring for etching are short.

### SUMMARY OF THE INVENTION

To solve the conventional problems, an object of the present invention is to provide a coating device of component for semiconductor manufacturing apparatus and coating method thereof in that a basic material has an improved erosion resistance, decay resistance and plasma resistance by forming a film of AIN, SICN, SIN, DLC, ALO, ALF and ALNO being with a certain thickness due to form a plasma by supplying a pulse RF and a DC voltage.

In order to achieve the object the present invention provides a coating device of component for semiconductor manufacturing apparatus comprising: a source among pulse type plasma source, ICP source, CCP source, CCP+ICP source and plasma source using a remote plasma to be carried out nitride treatment by a gas among N2, NH3, CH4 and N2O being supplied into a chamber; and DC voltage for forming a plasma by said source and for supplying 50 KeV˜100 KeV of voltage toward a susceptor placed thereon with a basic material or a pulse voltage for injecting ion.

In order to achieve the object the present invention provides a coating method of component for semiconductor manufacturing apparatus comprising the steps of: leading N⁺ ions excited by a plasma toward a basic material; penetrating said N⁺ ions into the basic material; reacting said N⁺ ions with said basic material to form a compound among AlN, SiN, SiCN, Carbone; and forming a coating layer having 100 nm˜2 μm of thickness on the basic material.

In order to achieve the object the present invention provides a coating method of component for semiconductor manufacturing apparatus comprising the steps of: leading carbon ions excited by a plasma toward a basic material; penetrating said carbon ions into the basic material; reacting said carbon ions with said basic material to form a carbone; and forming a coating layer having 100 nm˜2 μm of thickness on the basic material.

In order to achieve the object the present invention provides a coating device comprising: a shower head, a cathode and an edge ring facing to a heater or an electrostatic chuck having AlxNy, SixNy and SixCyNz layer as a coating layer that changes compound condition according to thickness toward a direction of depth.

In order to achieve the object the present invention provides a coating device comprising: a cathode and an edge ring facing to the electrostatic chuck having a carbone coating layer having 100 nm˜2 μm of thickness.

### BRIEF DESCRIPTION OF THE DRAWINGS

The above Object, features and advantages of the present invention will be more clearly understood from the following detailed description taken in conjunction with the accompanying drawings, in which:

FIG. 1 is a structure view of a conventional vacuum chamber of a semiconductor manufacturing device.

FIG. 2 is a structure view of a vacuum chamber of a semiconductor etching device.

FIG. 3 is a concept view of coating of a component of a semiconductor manufacturing device according to a present invention.

FIG. 4 is a graph of a supplying voltage and a coating thickness according to a present invention.

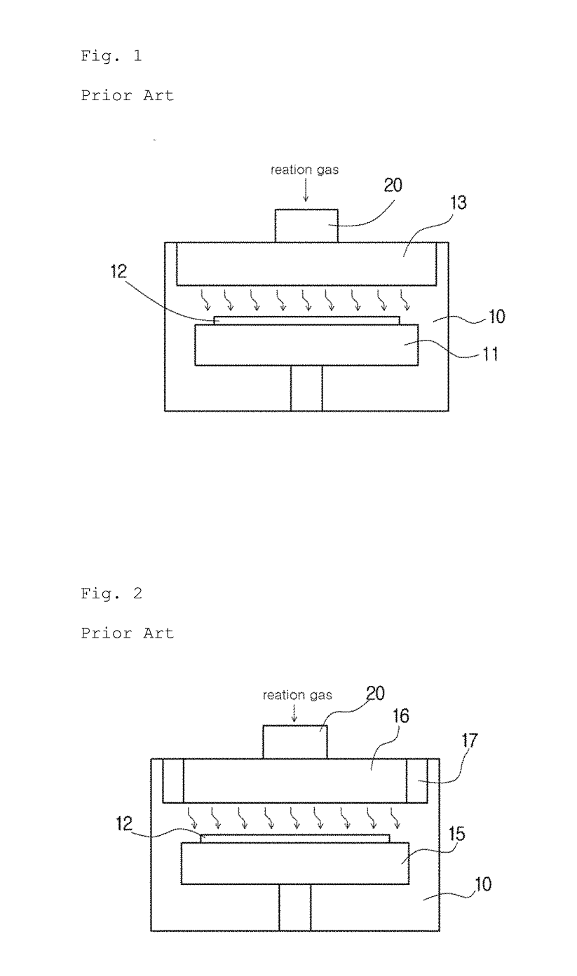

### DESCRIPTION OF PREFERRED EMBODIMENTS

Hereinafter, a device according to the preferred embodiment of the present invention will be described in detail with reference to the accompanying drawings.

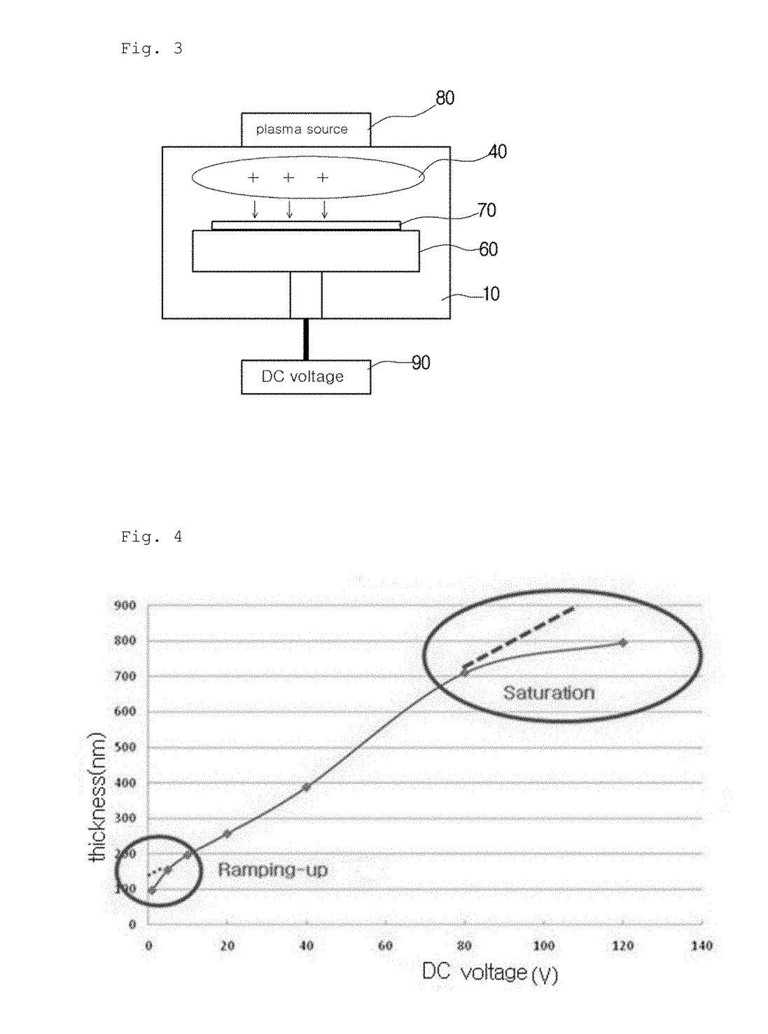

FIG. 3 is a concept view of coating of a component of a semiconductor manufacturing device according to a present invention and FIG. 4 is a graph of a supplying voltage and a coating thickness according to a present invention.

In the present invention, a plasma is supplied to a shower head in a chamber to ionize N2 gas and a bias voltage is supplied to the lower part of the chamber in order for N⁺ ion to diffuse and penetrate into a basic material made of one material among Hastelloy, Inconel, Si, SiC as Al, Ni and Ni alloy.

Accordingly, Al and N are combined in the basic material to form a AlN compound. As the above description, the present invention serves the coating method of the basic material that a desired material is directly penetrated into the metal basic material to form a compound in the basic material.

That is, in the present invention a plasma source 80 having a pulse type is supplied to the chamber to form the plasma and a DC voltage 90 is supplied toward a susceptor 60 having the basic material thereon, for example made of aluminum.

Accordingly, N⁺ ions excited by the plasma are leaded toward the basic material 70 made of Al, Si, SiC to be penetrated into the basic material. Furthermore, the N⁺ ions penetrated into the basic material 70 made of Al, Si, SiC react with Al, Si, SiC of the basic material 70 to form the compound of AlN, SiN, SiCN. Therefore, the coating layer having 100 nm˜2 μm of the thickness is formed on the basic material.

Furthermore, the N⁺ ions are injected into the basic material made of SiC under a state of the plasma environment and the pulse voltage below DC 30 KV is supplied under a state of CH4 environment form a Diamond Like Carbone structure. Accordingly, erosion resistance and decay resistance can be greatly improved.

The basic material made of one material among Al, Ni, SI, SIC, DLC, ALO, ALF and ALNO is carried out fluorine pre-treatment to be penetrated well the N⁺ ions and is changed into nitride condition under 300 [symbol] ˜650 [symbol] of the temperature or is used the plasma. At this time, the basic material is treated its surface by being injected a gas including fluorine at a state of 300 [symbol] ˜650 [symbol] as the pre-treatment temperature.

A fluorine compound is a fluorine compound gas at least one kind selected among the groups composing NF3, F2, BF3, CF4, SF6, WF6, CHF3, SiF4 and F2 gas produced by thermal decomposition or plasma of the fluorine compound gas. The basic material is treated its surface by immersing into solution including fluorine, for example HF+SC1.

Meanwhile, to increase the density of the plasma ICP source instead of the pulse RF can be used. Furthermore, CCP source or CCP+ICP source or remote plasma can be used to increase the area of the surface being treated of the basic material.

Furthermore, a pulse voltage instead of the DC voltage can be supplied to the chamber to improve the effect of the ion injection.

As the result of measuring the thickness by split evaluation from 1 KeV to 120 KeV as the voltage supplied to the lower part of the chamber, as shown in FIG. 4 we obtained 96 nm at 1 KeV and the thickness is increased linearly from 5 KeV.

Furthermore, we obtained 795 nm at 120 KeV, however, the thickness was saturated as being not linearly increased from 80 KeV. Accordingly, we found that the optimum condition is 5 KeV˜80 KeV of the temperature to obtain a desired thickness.

Meanwhile, in the present invention a shower head, a cathode and an edge ring facing to a heater or an electrostatic chuck are formed AlxNy, SixNy and SixCyNz layer as a coating layer that changes compound condition according to thickness toward a direction of depth.

Furthermore, in the present invention a cathode and an edge ring facing to the electrostatic chuck having a carbone coating layer having 100 nm˜2 μm of thickness.

What is claimed is:

1. A coating device of component for semiconductor manufacturing apparatus comprising:
a source among pulse type plasma source, ICP source, CCP source, CCP+ICP source and plasma source using a remote plasma to be carried out nitride treatment by a gas among N2, NH3, CH4 and N2O being supplied into a chamber; and
a DC voltage for forming a plasma by said source and for supplying 50 KeV˜100 KeV of voltage toward a susceptor placed thereon with a basic material or a pulse voltage for injecting ion.

2. A coating method of component for semiconductor manufacturing apparatus comprising the steps of:
leading N⁺ ions excited by a plasma toward a basic material;
penetrating said N⁺ ions into the basic material;
reacting said N⁺ ions with said basic material to form a compound among AlN, SiN, SiCN, Carbon; and
forming a coating layer having 100 nm˜2 μm of thickness on the basic material.

3. A coating method of component for semiconductor manufacturing apparatus comprising the steps of:
leading carbon ions excited by a plasma toward a basic material;
penetrating said carbone ions into the basic material;
reacting said carbone ions with said basic material to form a carbone; and
forming a coating layer having 100 nm˜2 μm of thickness on the basic material.

4. In a coating device of component for semiconductor manufacturing apparatus comprising a device for supplying a reaction gas at an upper part and a heater for placing a wafer thereon or an electrostatic chuck for fixing a wafer thereon at a lower part,
wherein the coating device comprises a shower head, a cathode and an edge ring facing to a heater or an electrostatic chuck having AlxNy, SixNy and SixCyNz layer as a coating layer that changes compound condition according to thickness toward a direction of depth.

5. In a coating device of component for semiconductor manufacturing apparatus comprising a device for supplying a reaction gas at an upper part and an electrostatic chuck for fixing a wafer thereon at a lower part,
wherein the coating device comprises a cathode and an edge ring facing to the electrostatic chuck having a carbon coating layer having 100 nm˜2 μm of thickness.
